(19) United States
(12) Patent Application Publication
(10) Pub. No.: US 2010/0252884 A1
(43) Pub. Date: Oct. 7, 2010

(54) SEMICONDUCTOR DEVICE

(75) Inventor: Yoji KITANO, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/730,563

(22) Filed: Mar. 24, 2010

(30) Foreign Application Priority Data
Apr. 1, 2009 (JP) 2009-088658

(51) Int. Cl. H01L 29/786

(52) U.S. Cl. 257/348; 257/E29.273

(57) ABSTRACT

A semiconductor device includes: an insulating layer; a semiconductor layer formed on the insulating layer; a first partially depleted transistor formed in the semiconductor layer; and a second transistor formed in the semiconductor layer, wherein the first transistor has a first gate electrode formed above the semiconductor layer via an insulating film and a first source or a first drain of a first conductivity type formed in the semiconductor layer below both sides of the first gate electrode, the second transistor has a second gate electrode formed above the semiconductor layer via an insulating film and a second source or a second drain of a second conductivity type formed in the semiconductor layer below both sides of the second gate electrode, and one of the second source and the second drain is electrically connected to the semiconductor layer in a region just below the first gate electrode.

The entire disclosure of Japanese Patent Application No. 2009-088658, filed Apr. 1, 2009 is expressly incorporated by reference herein.

### BACKGROUND

1. Technical Field

The present invention relates to a semiconductor device provided with a partially depleted transistor in a semiconductor layer on an insulating layer.

2. Related Art

The development and practical application of a technology of forming a semiconductor device in a thin semiconductor film formed on an insulating film (silicon on insulator (SOI)) are progressing for a low-power semiconductor device in the next generation. The SOI has advantages such as a high ON/OFF ratio or steep subthreshold characteristic of a drain current, low noise, and a low parasitic capacitance, and the application thereof to integrated circuits used for watches, mobile devices, and the like is progressing. At present, a metal insulator semiconductor field effect transistor (MISFET) having an SOI structure is used for various semiconductor integrated circuits. Especially a MISFET having a partially depleted (PD) SOI structure (hereinafter referred to as a PD-SOI MISFET) that can be manufactured easily in the same manner as the manufacturing method of a MISFET having a bulk structure in the related art is widely applied to semiconductor products. The structure of the PD-SOI MISFET is disclosed in, for example, JP-A-2004-128254.

In the PD-SOI MISFET, a body region is electrically isolated from other regions by means of an element isolation film and an insulating layer (also referred to as a BOX layer), and the potential of the body region (that is, a body potential) floats. Therefore, the influence of a phenomenon called a substrate floating effect on device characteristics (for example, a history effect) has to be considered. The history effect is a phenomenon in which a body potential and a drain current fluctuate due to the history of voltage having been applied to a gate, a drain, and a source, causing unstable device characteristics.

The history effect can be suppressed by a known body potential fixing method shown in, for example, FIGS. 8A and 8B.

FIGS. 8A and 8B are a plane view and a cross-sectional view showing a configuration example of a PD-SOI MISFET 90 according to the related art. As shown in FIGS. 8A and 8B, the PD-SOI MISFET 90 has a gate insulating film 93 formed on the surface of an SOI layer 92 on a BOX layer 91, a gate electrode 94 formed above the SOI layer 92 via the gate insulating film 93, an N-type source 95a or drain 95b formed in the SOI layer 92 below both sides of the gate electrode 94, and a P⁺ layer 96 connected to the SOI layer 92 in a region just below the gate electrode 94 (that is, a body region).

In the PD-SOI MISFET 90, a depletion layer 92a does not reach the BOX layer 91, and a neutral region 92b is left, during its operation as shown in FIG. 8B. Since the potential of the body region 92 (that is, a body potential) is fixed to a desired potential (for example, a ground potential) via a contact 97 and the P⁺ layer 96, the substrate floating effect is suppressed, and the history effect is suppressed. Such a structure is called body contact, or also called body tie, which is disclosed in, for example, JP-A-2004-119884.

In FIG. 8A, an inter-layer insulating film 98 shown in FIG. 8B is omitted for the convenience.

In the PD-SOI MISFET 90, when the body potential is fixed (that is, in the case of the body contact), device characteristics become stable, but on the other hand, a parasitic capacitance is generated in the body region. Therefore, an ON current is reduced, leading to problems of a reduction in ON/OFF ratio or increase in subthreshold swing value (S value) of a drain current, and the like. That is, there is a problem in that the drive current of the PD-SOI MOSFET 90 is reduced, whereby the current drive ability thereof becomes substantially equal to that of bulk silicon. Therefore, in the structure shown in FIGS. 8A and 8B, it might be impossible to make full use of the advantages of the SOI.

### SUMMARY

An advantage of some aspects of the invention is to provide a semiconductor device in which a high ON/OFF ratio and stable operation can be realized simultaneously in a partially depleted transistor formed in a semiconductor layer on an insulating layer.

A semiconductor device according to an aspect of the invention includes: an insulating layer; a semiconductor layer formed on the insulating layer; a first partially depleted transistor formed in the semiconductor layer; and a second transistor formed in the semiconductor layer, wherein the first transistor has a first gate electrode formed above the semiconductor layer via an insulating film and a first source or a first drain of a first conductivity type formed in the semiconductor layer below both sides of the first gate electrode, the second transistor has a second gate electrode formed above the semiconductor layer via an insulating film and a second source or a second drain of a second conductivity type formed in the semiconductor layer below both sides of the second gate electrode, and one of the second source and the second drain is electrically connected to the semiconductor layer in a region just below the first gate electrode.

Here, the “insulating layer” is also called a BOX layer, for example, and the “semiconductor layer” is also called an SOI layer, for example. The “partially depleted transistor” is a transistor in which during the operation of the transistor, a semiconductor layer in a region just below a gate electrode (that is, a body region) is not completely depleted but partially depleted (that is, a depletion layer does not reach an insulating layer, and a neutral region is left). The insulating film between the gate electrode and the semiconductor layer may be a gate oxide film formed by thermal oxidation of the semiconductor layer or may be another insulating film (for example, a high-k film).

With such a configuration, when the first transistor is ON, the second transistor can be OFF, and when the first transistor is OFF, the second transistor can be ON. Therefore, the first transistor can be switched between a body floating structure and a body contact structure in accordance with the ON and OFF of the first transistor. That is, when the first transistor is ON, the first transistor can have the body floating structure (that is, the body potential can float). When the first transistor is OFF, the first transistor can have the body contact structure (that is, the body potential can be fixed).

In this case, an ON current of the first transistor is increased due to an effect of body floating, while an OFF current is reduced due to an effect of body contact. Since the body potential of the first transistor is reset due to the effect of body contact when the first transistor is OFF, the history effect is suppressed in the first transistor. Accordingly, a high ON/OFF ratio and stable operation can be realized simultaneously in the first transistor.

The semiconductor device may be configured such that the first gate electrode and the second gate electrode are electrically connected to each other. With such a configuration, the first gate electrode can always have the same potential as the second gate electrode, so that the switching between the ON and OFF of the first transistor and the switching between the OFF and ON of the second transistor can be synchronized. Since a signal line can be connected in common to the first gate electrode and the second gate electrode, the number of signal lines and the number of terminals can be reduced compared to the case where the first gate electrode and the second gate electrode are electrically isolated from each other.

Also, the semiconductor device may be configured such that the first gate electrode and the second gate electrode are electrically isolated from each other. With such a configuration, it is possible to select whether the switching between the ON and OFF of the first transistor and the switching between the OFF and ON of the second transistor are synchronized or not. The degree of design freedom can be enhanced compared to the case where the first gate electrode and the second gate electrode are electrically connected to each other.

The semiconductor device may be configured to further include a third partially depleted transistor formed in the semiconductor layer and a fourth transistor formed in the semiconductor layer. The third transistor has a third gate electrode formed above the semiconductor layer via an insulating film and a third source or a third drain of the second conductivity type formed in the semiconductor layer below both sides of the third gate electrode. The fourth transistor has a fourth gate electrode formed above the semiconductor layer via an insulating film and a fourth source or a fourth drain of the first conductivity type formed in the semiconductor layer below both sides of the fourth gate electrode. One of the fourth source and the fourth drain is electrically connected to the semiconductor layer in a region just below the second gate electrode. The first transistor and the third transistor constitute an inverter circuit.

With such a configuration, when the third transistor is ON, the body region can have the body floating structure, while the third transistor is OFF, the body region can have the body contact structure. Accordingly, also in the third transistor, the ON current is increased, the OFF current is reduced, and the history effect is suppressed, in the same manner as in the first transistor. Accordingly, it is possible to provide an inverter circuit in which a high ON/OFF ratio and stable operation are realized simultaneously.

The semiconductor device may be configured such that the third gate electrode and the fourth gate electrode are electrically connected to each other. With such a configuration, the third gate electrode can be fixed at the same potential as the fourth gate electrode, so that the switching between the ON and OFF of the third transistor and the switching between the OFF and ON of the fourth transistor can be synchronized. The number of signal lines and the number of terminals can be reduced compared to the case where the third gate electrode and the fourth gate electrode are electrically isolated from each other.

The semiconductor device may be configured such that the third gate electrode and the fourth gate electrode are electrically isolated from each other. With such a configuration, it is possible to select whether the switching between the ON and OFF of the third transistor and the switching between the OFF and ON of the fourth transistor are synchronized or not. The degree of design freedom can be enhanced compared to the case where the third gate electrode and the fourth gate electrode are electrically connected to each other.

### BRIEF DESCRIPTION OF THE DRAWINGS

The invention will be described with reference to the accompanying drawings, wherein like numbers reference like elements.

FIGS. 1A and 1B show a configuration example of a semiconductor device according to a first embodiment of the invention.

FIG. 2 shows the transfer characteristics of transistors 10 and 20.

FIGS. 3A and 3B show a configuration example of a semiconductor device according to a second embodiment of the invention.

FIG. 4 shows the transfer characteristics of transistors 30 and 40.

FIGS. 5A and 5B show a configuration example of a semiconductor device according to a third embodiment of the invention.

FIG. 6 shows a configuration example of a semiconductor device according to a fourth embodiment of the invention.

FIG. 7 shows a configuration example of a semiconductor device according to a fifth embodiment of the invention.

FIGS. 8A and 8B show an example of related art.

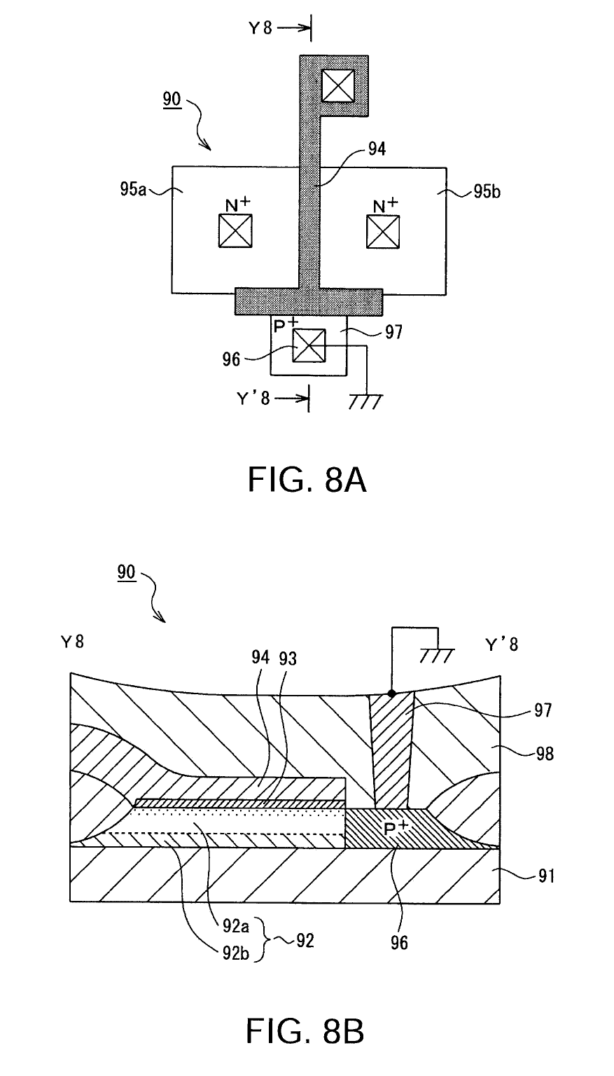

FIG. 9 schematically shows a change in Vth due to impact ionization.

### DESCRIPTION OF EXEMPLARY EMBODIMENTS

Hereinafter, embodiments of the invention will be described with reference to the drawings. In the drawings described below, the same reference numeral is assigned to a portion having the same configuration, and the repetitive description thereof is omitted.

### 1 First Embodiment

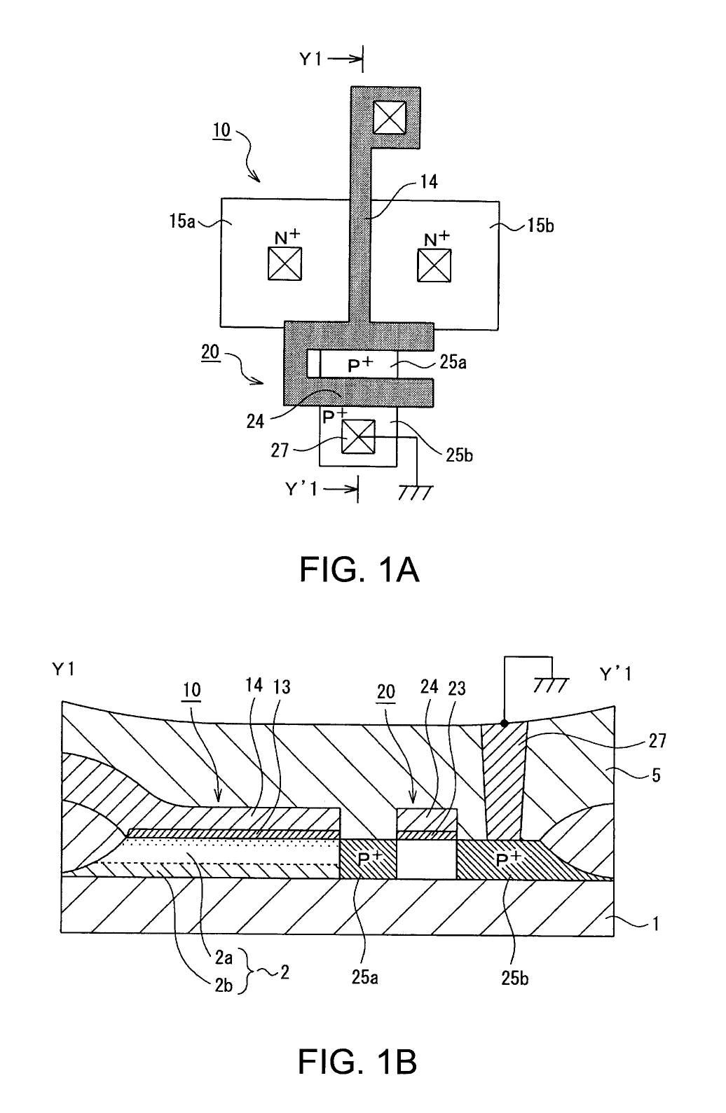

FIGS. 1A and 1B are a plan view and a cross-sectional view showing a configuration example of a semiconductor device according to a first embodiment of the invention. As shown in FIGS. 1A and 1B, the semiconductor device includes a first N-channel transistor 10 and a second P-channel transistor 20 formed in an SOI layer 2 on a BOX layer 1. The BOX layer 1 is a silicon oxide film (SiO₂), for example. The SOI layer 2 is a single-crystal silicon layer (Si), for example.

The first transistor 10 has, for example, a gate electrode 14 formed above the SOI layer 2 via an insulating film 13 and an N-type source 15a or drain 15b formed in the SOI layer 2 below both sides of the gate electrode 14. The first transistor 10 is a partially depleted MISFET (that is, a PD-SOI MISFET). During the operation of the transistor, a depletion layer 2a does not reach the BOX layer 1, and a neutral region 2b is left, in the SOI layer 2 in a region just below the gate electrode 14 (that is, a body region) as shown in FIG. 1B. The second transistor 20 is also, for example, a PD-SOI MISFET and has a gate electrode 24 formed above the SOI layer 2 via an insulating film 23 and a P-type source 25a or drain 25b formed in the SOI layer 2 below both sides of the gate electrode 24. The insulating films 13 and 23 are each a gate oxide film (SiO₂ or SiON) formed by, for example, thermal oxidation of the SOI layer 2, or a high-k film. The gate electrodes 14 and 24 are formed of polysilicon containing an impurity such as, for example, phosphorus or boron.

As shown in FIG. 1B, in the semiconductor device, one of the source 25a and the drain 25b is arranged so as to be in direct contact with the body region 2 of the first transistor 10. In doing so, one of the source 25a and the drain 25b can be electrically connected to the body region 2 of the first transistor 10. Moreover, the other of the source 25a and the drain 25b can be connected to a fixed potential via a contact 27. The fixed potential is a ground potential, or a power supply VSS or VDD, for example. In the semiconductor device, as shown in FIG. 1A, the gate electrodes 14 and 24 are electrically connected to each other. In FIG. 1A, an inter-layer insulating film 5 is omitted for avoiding complication of the drawing.

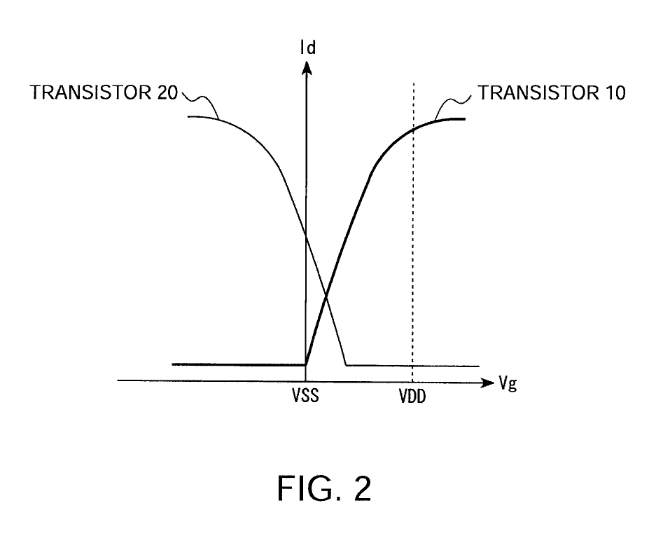

FIG. 2 schematically shows the transfer characteristics (that is, Vg-Id characteristics) of the first transistor 10 and the second transistor 20. In FIG. 2, the horizontal axis represents a gate voltage Vg, while the vertical axis represents a drain current Id. As shown in FIG. 2, in the first N-channel transistor 10, when the gate voltage Vg is increased in a direction from VSS to VDD under the condition where a drain voltage Vd is constant, the drain current Id is also increased in response to the increase. In the second P-channel transistor 20, on the other hand, when the gate voltage Vg is increased in the direction from VSS to VDD under the condition where the drain voltage Vd is constant, the drain current Id is decreased in response to the increase.

In the first embodiment of the invention, a threshold voltage Vth of the first transistor 10 and the Vth of the second transistor 20 are controlled such that when the first transistor 10 is ON (that is, when the drain current Id having at least a desired magnitude flows), the second transistor 20 is OFF, and when the first transistor 10 is OFF, the second transistor 20 is ON.

For example, the first transistor 10 is set to the enhancement type, while the second transistor 20 is set to the depletion type. The respective voltages Vth of the first transistor 10 and the second transistor 20 are controlled such that when the potential of the gate electrodes 14 and 24 is at VSS (for example, 0 V) or less, the first transistor 10 is OFF, and the second transistor 20 is ON, and when the potential of the gate electrodes 14 and 24 is at Vx (VSS<Vx<VDD), the first transistor 10 is ON, and the second transistor 20 is OFF (The first transistor 10 is not necessarily limited to the enhancement type, and the second transistor 20 is not necessarily limited to the depletion type. Depending on other characteristics of the device, the first transistor 10 may be of the depletion type, and the second transistor 20 may be of the enhancement type. Alternatively, both the first transistor 10 and the second transistor 20 may be of the enhancement type, and both of them may be of the depletion type.).

According to the first embodiment of the invention as described above, when the first transistor 10 is ON, the second transistor 20 is OFF, and when the first transistor 10 is OFF, the second transistor 20 is ON, so that the first transistor 10 can be switched between the body floating structure and the body contact structure in accordance with the ON and OFF of the first transistor 10. That is, when the first transistor 10 is ON, the first transistor 10 can have the body floating structure (that is, the body potential can float). When the first transistor 10 is OFF, the first transistor can have the body contact structure (that is, the body potential can be fixed).

In this case, the ON current of the first transistor 10 is increased due to the effect of body floating, while the OFF current is reduced due to the effect of body contact. Since the body potential of the first transistor 10 is reset due to the effect of body contact when the first transistor 10 is OFF, the history effect is suppressed in the first transistor 10. Accordingly, a high ON/OFF ratio and stable operation can be realized simultaneously in the first transistor 10.

In the first embodiment, the BOX layer 1 corresponds to an “insulating layer” of the invention, and the SOI layer 2 corresponds to a “semiconductor layer” of the invention. The first transistor 10 corresponds to a “first transistor” of the invention, the gate electrode 14 corresponds to a “first gate electrode” of the invention, the source 15a corresponds to a “first source” of the invention, and the drain 15b corresponds to a “first drain” of the invention. The second transistor 20 corresponds to a “second transistor” of the invention, the gate electrode 24 corresponds to a “second gate electrode” of the invention, the source 25a corresponds to a “second source” of the invention, and the drain 25b corresponds to a “second drain” of the invention.

Hereinafter, the reason why the OFF current is reduced in the invention will be described.

In a MISFET, impact ionization occurs (this is not a phenomenon inherent to SOI) under such a condition as the drain voltage Vd>1.1 V. Here, the impact ionization is a phenomenon in that numerous electron-hole pairs are generated due to the collision of charged particles and Si atoms. That is, in the case where charged particles (electrons in the case of n, and holes in the case of p) flowing through a channel when the channel is ON are accelerated by an electric field near a drain and collide with Si atoms with an energy of a certain level or higher (about 1.5 eV or higher), Si atoms are ionized due to the energy and release electrons. Along with the release of electrons, holes are also generated. That is, numerous electron-hole pairs are generated due to the impact ionization.

In the case of an N-channel MISFET, the generated electrons flow to a drain at a high potential, while holes flow to a body region at a low potential (the flows of electrons and holes are reversed in the case of a P-channel MISFET). In the case of the N-channel MISFET, the body potential is increased due to the supply of holes. In the case of the P-channel MISFET, the body potential is reduced due to the supply of electrons. In either case, the threshold voltage Vth of the MISFET is reduced due to the impact ion. Further, carriers themselves are also increased in number, leading to an increase of the ON current. In the case of SOI, since the body floats, the influence is obviously large compared to the case of bulk.

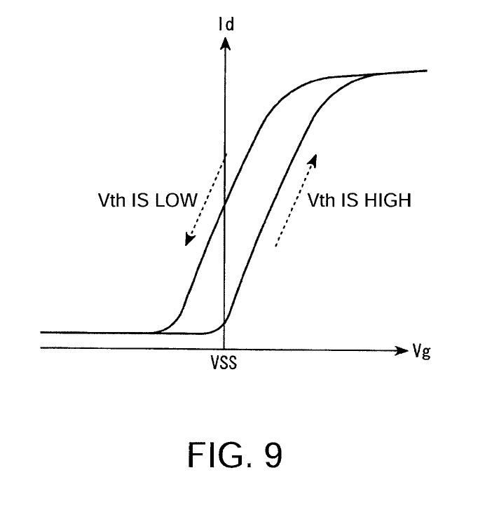

FIG. 9 schematically shows a change in Vth due to impact ionization in the case of an N-channel PD-SOI MISFET. When a channel current (that is, the ON current) flows, Vth is reduced due to impact ionization. Accordingly, since Vth is already reduced when the PD-SOI MISFET is changed from ON to OFF, the OFF current is increased. In the embodiment of the invention, on the other hand, since there is a path (that is, the second transistor 20) for discharging holes accumulated in the body region when the PD-SOI MISFET (that is, the first transistor 10) is OFF, the OFF current can be reduced.

### 2 Second Embodiment

The first embodiment has described a case in which a “first conductivity type” of the invention is N-type, and a “second conductivity type” is P-type. However, the invention is not limited thereto. The “first conductivity type” may be P-type, and the “second conductivity type” may be N-type.

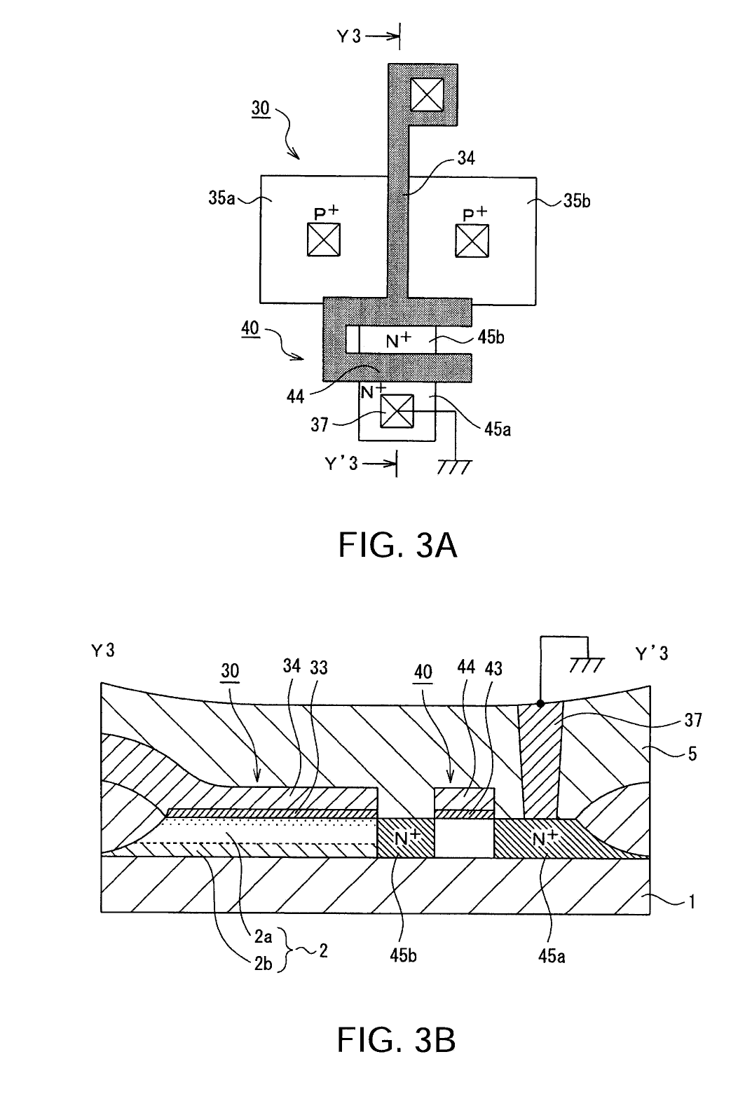

FIGS. 3A and 3B are a plan view and a cross-sectional view showing a configuration example of a semiconductor device according to a second embodiment of the invention. As shown in FIGS. 3A and 3B, the semiconductor device includes a first P-channel transistor 30 and a second N-channel transistor 40 formed in the SOI layer 2 on the BOX layer 1.

The first transistor 30 has, for example, a gate electrode 34 formed above the SOI layer 2 via an insulating film 33 and a P-type source 35a or drain 35b formed in the SOI layer 2 below both sides of the gate electrode 34. The first transistor 30 is a PD-SOI MISFET. As shown in FIG. 3B, during the operation of the transistor, the depletion layer 2a does not reach the BOX layer 1, and the neutral region 2b is left. The second transistor 40 is also, for example, a PD-SOI MISFET and has a gate electrode 44 formed above the SOI layer 2 via an insulating film 43 and an N-type source 45a or drain 45b formed in the SOI layer 2 below both sides of the gate electrode 44. The insulating films 33 and 43 are each a gate oxide film (SiO₂ or SiON) formed by, for example, thermal oxidation of the SOI layer 2, or a high-k film. The gate electrodes 34 and 44 are formed of polysilicon containing an impurity such as, for example, phosphorus or boron.

As shown in FIG. 3B, in the semiconductor device, one of the source 45a and the drain 45b is arranged so as to be in direct contact with the body region 2 of the first transistor 30. In doing so, one of the source 45a and the drain 45b can be electrically connected to the body region 2 of the first transistor 30. Moreover, the other of the source 45a and the drain 45b can be connected to a fixed potential via a contact 37. As shown in FIG. 3A, the gate electrodes 34 and 44 are electrically connected to each other. In FIG. 3A, the inter-layer insulating film 5 is omitted for avoiding complication of the drawing.

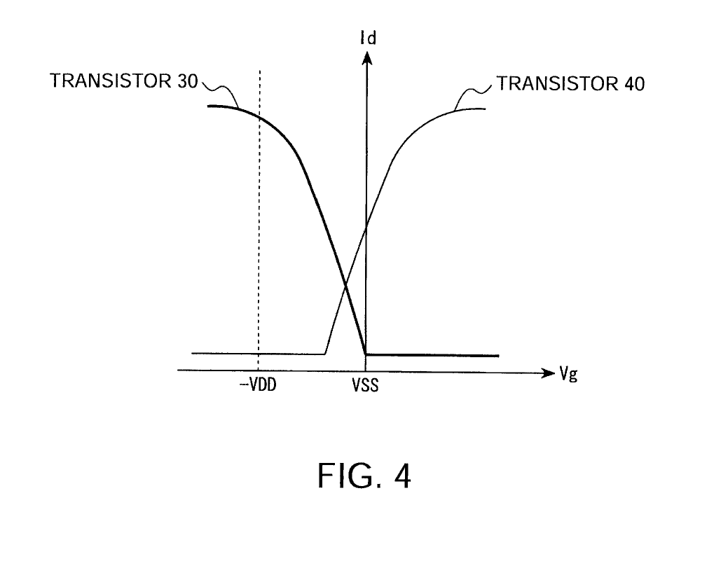

FIG. 4 schematically shows the transfer characteristics (that is, Vg-Id characteristics) of the first transistor 30 and the second transistor 40. In FIG. 4, the horizontal axis represents the gate voltage Vg, while the vertical axis represents the drain current Id. As shown in FIG. 4, in the first P-channel transistor 30, when the gate voltage Vg is increased in the direction from VSS to VDD under the condition where the drain voltage Vd is constant, the drain current Id is decreased in response to the increase. In the second N-channel transistor 40, on the other hand, when the gate voltage Vg is increased in the direction from VSS to VDD under the condition where the drain voltage Vd is constant, the drain current Id is also increased in response to the increase.

In the second embodiment of the invention, the Vth of the first transistor 30 and the Vth of the second transistor 40 are controlled such that when the first transistor 30 is ON, the second transistor 40 is OFF, and when the first transistor 30 is OFF, the second transistor 40 is ON. For example, the first transistor 30 is set to the enhancement type, while the second transistor 40 is set to the depletion type. The respective voltages Vth of the first transistor 30 and the second transistor 40 are controlled such that when the potential of the gate electrodes 34 and 44 is at VSS (for example, 0 V) or more, the first transistor 30 is OFF, and the second transistor 40 is ON, and when the potential of the gate electrodes 34 and 44 is at Vx (VSS>Vx>VDD), the first transistor 30 is ON, and the second transistor 40 is OFF.

According to the second embodiment of the invention as described above, when the first transistor 30 is ON, the first transistor 30 can have the body floating structure in the same manner as in the first embodiment. When the first transistor 30 is OFF, the first transistor 30 can have the body contact structure. Accordingly, a high ON/OFF ratio and stable operation can be realized simultaneously in the first transistor 30.

In the second embodiment, the first transistor 30 corresponds to the “first transistor” of the invention, the gate electrode 34 corresponds to the “first gate electrode” of the invention, the source 35a corresponds to the “first source” of the invention, and the drain 35b corresponds to the “first drain” of the invention. The second transistor 40 corresponds to the “second transistor” of the invention, the gate electrode 44 corresponds to the “second gate electrode” of the invention, the source 45a corresponds to the “second source” of the invention, and the drain 45b corresponds to the “second drain” of the invention. The other correspondence relations are the same as those in the first embodiment.

### 3 Third Embodiment

The first and second embodiments have described a case in which the gate electrode of the first transistor and the gate electrode of the second transistor are electrically connected to each other. With this configuration, the gate electrodes can always have the same potential, so that the switching between the ON and OFF of the first transistor and the switching between the OFF and ON of the second transistor can be synchronized. However, the invention is not limited thereto.

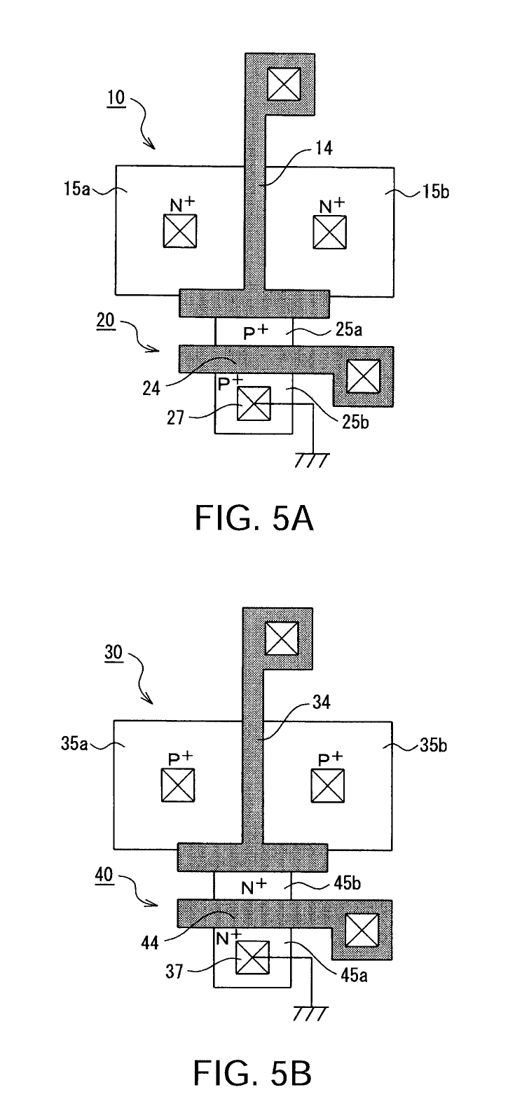

FIGS. 5A and 5B are plan views each showing a configuration example of a semiconductor device according to a third embodiment of the invention. In the invention as shown in FIG. 5A, the gate electrode 14 of the first transistor 10 and the gate electrode 24 of the second transistor 20 may be electrically isolated from each other. Moreover, as shown in FIG. 5B, the gate electrode 34 of the first transistor 30 and the gate electrode 44 of the second transistor 40 may be electrically isolated from each other.

With such a configuration, the number of signal lines and the number of terminals are increased compared to the first and second embodiments because the signal lines are separately connected to the gate electrodes. However, it becomes possible to select whether the switching between the ON and OFF of the first transistor and the switching between the OFF and ON of the second transistor are synchronized or not.

In FIG. 5A for example, when voltage is applied to the gate electrode 14 and the gate electrode 24 at the same timing, the switching between the ON and OFF of the first transistor 10 and the switching between the OFF and ON of the second transistor 20 can be performed simultaneously. When voltage is applied to the gate electrode 14 and the gate electrode 24 at different timings, the switching between the ON and OFF of the first transistor 10 and the switching between the OFF and ON of the second transistor 20 can be performed independently of each other. Therefore, the degree of design freedom of the semiconductor device can be enhanced compared to the first and second embodiments. Relations corresponding to the invention in the third embodiment are the same as those in the first and second embodiments.

### 4 Fourth Embodiment

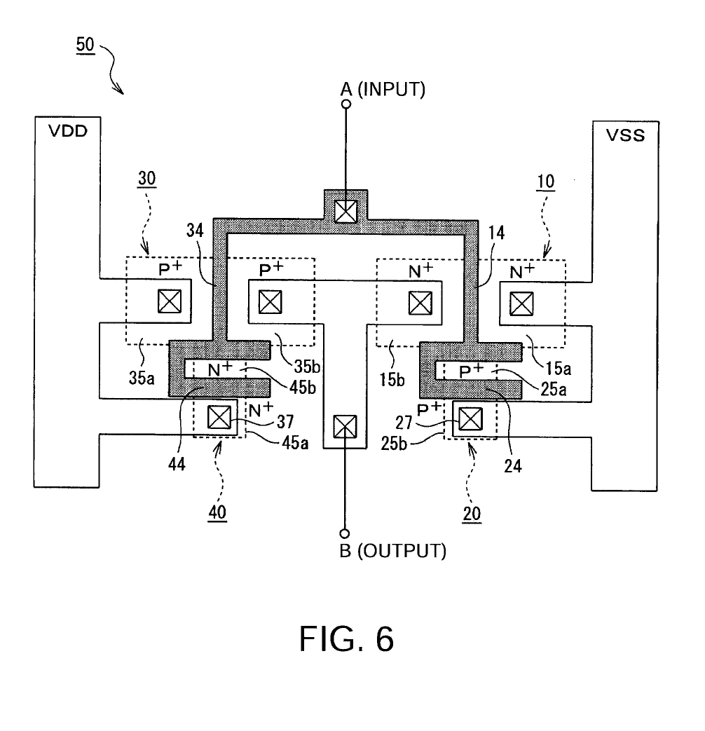

FIG. 6 is a plan view showing a configuration example of a semiconductor device according to a fourth embodiment of the invention. As shown in FIG. 6, the semiconductor device has, for example, the first transistor 10 and the second transistor 20, described in the first embodiment, and the first transistor (hereinafter referred to as a third transistor for the convenience of description) 30 and the second transistor (hereinafter referred to as a fourth transistor for the same reason) 40, described in the second embodiment. The transistors are combined to constitute a CMOS inverter circuit 50.

That is, the CMOS inverter circuit 50 includes the first transistor 10, the second transistor 20, the third transistor 30, and the fourth transistor 40. The source 15a of the first transistor 10 and a power supply line VSS are electrically connected to each other. The drain 15b of the first transistor 10 and the drain 35b of the third transistor 30 are electrically connected to each other. The source 35a of the third transistor 30 is connected to a power supply line VDD. The drain 25b of the second transistor 20 is electrically connected to VSS. The source 25a of the second transistor 20 is electrically connected to the body region of the first transistor 10. The source 45a of the fourth transistor 40 is connected to VDD. The drain 45b of the fourth transistor 40 is connected to the body region of the third transistor 30.

The gate electrode 14 of the first transistor 10 and the gate electrode 34 of the third transistor 30 are both electrically connected to an input signal line A. The drain 15b of the first transistor 10 and the drain 35b of the third transistor 30 are both electrically connected to an output signal line B.

For example, when the potential of the input signal line A is at VDD (>VSS), the first transistor 10 is ON, and the third transistor 30 is OFF. Therefore, the potential of the output signal line B becomes substantially equal to VSS. Since the second transistor 20 is OFF in this case, the first transistor 10 has the body floating structure. Accordingly, the ON current of the first transistor 10 can be increased (compared to the body contact structure). On the other hand, since the fourth transistor 40 is ON, the third transistor 30 has the body contact structure. Accordingly, the OFF current of the third transistor 30 can be reduced (compared to the body floating structure). Further, since the body potential of the third transistor 30 is reset due to the body contact structure, the history effect is suppressed in the third transistor 30.

When the potential of the input signal line A is at −VDD (<VSS), the first transistor 10 is OFF, and the third transistor 30 is ON. Therefore, the potential of the output signal line B becomes substantially equal to VDD. Since the second transistor 20 is ON in this case, the first transistor 10 has the body contact structure. Accordingly, the OFF current of the first transistor 10 can be reduced (compared to the body floating structure). Further, since the body potential of the first transistor 10 is reset due to the body contact structure, the history effect is suppressed in the first transistor 10. On the other hand, since the fourth transistor 40 is OFF, the third transistor 30 has the body floating structure. Accordingly, the ON current of the third transistor 30 can be increased (compared to the body contact structure).

According to the third embodiment of the invention as described above, since the transistors 10, 20, 30, and 40 described in the first and second embodiments are applied, it is possible to provide the CMOS inverter circuit 50 in which a high ON/OFF ratio and stable operation are realized simultaneously.

In the fourth embodiment, the third transistor 30 corresponds to a “third transistor” of the invention, the gate electrode 34 corresponds to a “third gate electrode” of the invention, the source 35a corresponds to a “third source” of the invention, and the drain 35b corresponds to a “third drain” of the invention. The fourth transistor 40 corresponds to a “fourth transistor” of the invention, the gate electrode 44 corresponds to a “fourth gate electrode” of the invention, the source 45a corresponds to a “fourth source” of the invention, and the drain 45b corresponds to a “fourth drain” of the invention. The CMOS inverter circuit 50 corresponds to an “inverter circuit” of the invention. The other correspondence relations are the same as those in the first embodiment.

### 5 Fifth Embodiment

As shown in FIG. 6, the fourth embodiment has described a case in which all of the gate electrodes 14, 24, 34, and 44 are electrically connected to the input signal line A. However, the CMOS inverter circuit according to the invention is not limited thereto.

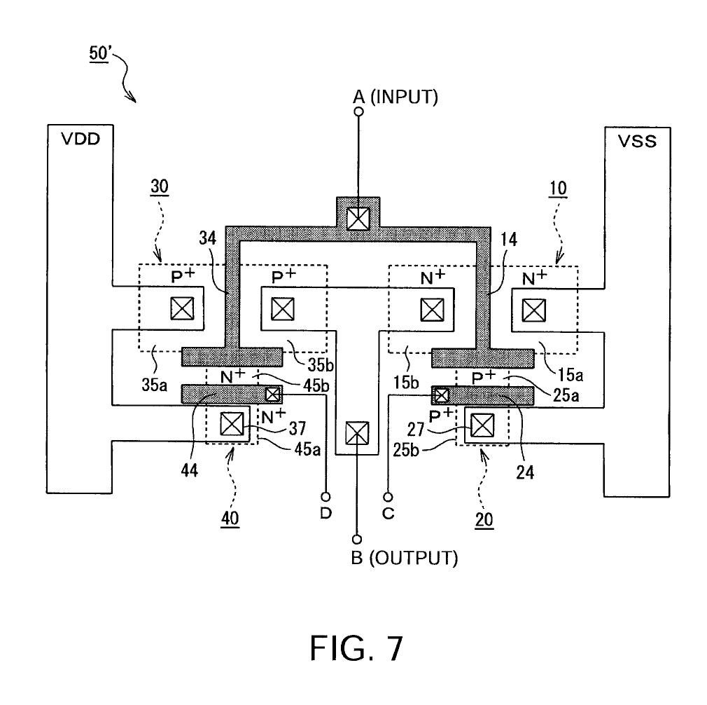

FIG. 7 is a plan view showing a configuration example of a semiconductor device according to a fifth embodiment of the invention. As shown in FIG. 7, in the CMOS inverter circuit according to the invention, the gate electrodes 14 and 24 may be electrically isolated from each other, and the gate electrodes 34 and 44 may be electrically isolated from each other. In that case, for example, a signal line C is electrically connected to the gate electrode 24, and a signal line D is connected to the gate electrode 44.

With such a configuration, the number of signal lines and the number of terminals are increased compared to the fourth embodiment. As described in the third embodiment, however, it becomes possible to select whether the switching between the ON and OFF of the first transistor 10 and the switching between the OFF and ON of the second transistor 20 are synchronized or not. Moreover, it becomes also possible to select whether the switching between the ON and OFF of the third transistor 30 and the switching between the OFF and ON of the fourth transistor 40 are synchronized or not. Therefore, it is possible to provide a CMOS inverter circuit 50′ in which the degree of design freedom is enhanced compared to the fourth embodiment. In the fifth embodiment, the CMOS inverter circuit 50′ corresponds to the “inverter circuit” of the invention. The other correspondence relations are the same as those in the fourth embodiment.

What is claimed is:

1. A semiconductor device comprising:
an insulating layer;
a semiconductor layer formed on the insulating layer;
a first partially depleted transistor formed in the semiconductor layer; and
a second transistor formed in the semiconductor layer, wherein
the first transistor has
a first gate electrode formed above the semiconductor layer via an insulating film and
a first source or a first drain of a first conductivity type formed in the semiconductor layer below both sides of the first gate electrode,
the second transistor has
a second gate electrode formed above the semiconductor layer via an insulating film and
a second source or a second drain of a second conductivity type formed in the semiconductor layer below both sides of the second gate electrode, and
one of the second source and the second drain is electrically connected to the semiconductor layer in a region just below the first gate electrode.

2. The semiconductor device according to claim 1, wherein the first gate electrode and the second gate electrode are electrically connected to each other.

3. The semiconductor device according to claim 1, wherein the first gate electrode and the second gate electrode are electrically isolated from each other.

4. The semiconductor device according to claim 1, further comprising:
a third partially depleted transistor formed in the semiconductor layer; and
a fourth transistor formed in the semiconductor layer, wherein
the third transistor has
a third gate electrode formed above the semiconductor layer via an insulating film and
a third source or a third drain of the second conductivity type formed in the semiconductor layer below both sides of the third gate electrode,
the fourth transistor has
a fourth gate electrode formed above the semiconductor layer via an insulating film and
a fourth source or a fourth drain of the first conductivity type formed in the semiconductor layer below both sides of the fourth gate electrode,
one of the fourth source and the fourth drain is electrically connected to the semiconductor layer in a region just below the second gate electrode, and
the first transistor and the third transistor constitute an inverter circuit.

5. The semiconductor device according to claim 4, wherein the third gate electrode and the fourth gate electrode are electrically connected to each other.

6. The semiconductor device according to claim 4, wherein the third gate electrode and the fourth gate electrode are electrically isolated from each other.
